(19) United States
(12) Patent Application Publication
(10) Pub. No.: US 2011/0180781 A1
(43) Pub. Date: Jul. 28, 2011

(54) Highly Polarized White Light Source By Combining Blue LED on Semipolar or Nonpolar GaN with Yellow LED on Semipolar or Nonpolar GaN

(75) Inventors: James W. Raring, Goleta, CA (US); Daniel F. Feezell, Goleta, CA (US)

(73) Assignee: Soraa, Inc, Goleta, CA (US)

(21) Appl. No.: 12/995,946

(22) PCT Filed: Jun. 9, 2009
(86) PCT No.: PCT/US09/46786

§ 371 Date: Feb. 28, 2011

Related U.S. Application Data
(60) Provisional application No. 61/059,251, filed on Jun. 5, 2008.

(51) Int. Cl. H01L 33/06; H01L 33/08

(52) U.S. Cl. 257/13; 257/76; 257/E33.025; 257/E33.008

(57) ABSTRACT

A packaged light emitting device. The device has a substrate member comprising a surface region. The device also has two or more light emitting diode devices overlying the surface region. Each of the light emitting diode device is fabricated on a semipolar or nonpolar GaN containing substrate. The two or more light emitting diode devices are fabricated on the semipolar or nonpolar GaN containing substrate emits substantially polarized emission.

### CITED PUBLICATIONS

[1] H. Zhong, A. Tyagi, N. N. Fellows, F. Wu, R. B. Chung, M. Saito, K. Fujito, J. S. Speck, S. P. DenBaars, and S. Nakamura, “High power and high efficiency blue light emitting diode on freestanding semipolar (1122) bulk GaN substrate,” Appl. Phys. Lett., vol. 90, 2007.

[2] H. Sato, A. Tyagi, H. Zhong, N. Fellows, R. Chung, M. Saito, K. Fujito, J. Speck, S. DenBaars, and S. Nakamura, “High power and high efficiency green light emitting diode on free-standing semipolar (1122) bulk GaN substrate,” Phys. Stat. Sol. (RRL), vol. 1, pp. 162-164, June 2007.

[3] H. Zhong, A. Tyagi, N. N. Fellows, R. B. Chung, M. Saito, K. Fujito, J. S. Speck, S. P. DenBaars, and S. Nakamura, “Demonstration of high power blue-green light emitting diode on semipolar (1122) bulk GaN substrate,” Elect. Lett., vol. 43, pp. 825-826.

### DESCRIPTION OF EMBODIMENTS OF THE INVENTION

The present invention relates generally to lighting techniques. More specifically, embodiments of the invention include techniques for combining different colored LED devices, such as blue and yellow, fabricated on bulk semipolar or nonpolar materials. Merely by way of example, the invention can be applied to applications such as white lighting, multi-colored lighting, lighting for flat panels, other optoelectronic devices, and the like.

Recent breakthroughs in the field of GaN-based optoelectronics have demonstrated the great potential of devices fabricated on bulk nonpolar and semipolar GaN substrates. The lack of strong polarization induced electric fields on these orientations leads to a greatly enhanced radiative recombination efficiency in InGaN emitting layers over conventional devices fabricated on c-plane GaN. Furthermore, the electronic band structure along with the anisotropic nature of the strain leads to highly polarized light emission, which will offer several advantages in applications such as display backlighting.

Of particular importance to the field of lighting is the progression of light emitting diodes (LED) fabricated on semipolar GaN substrates. Such devices making use of InGaN light emitting layers have exhibited record output powers at extended operation wavelengths into the blue region (430-470 nm) and the green region (510-530 nm). One promising semipolar orientation is the (11-22) plane. This plane is inclined by 58.4o with respect to the c-plane. University of California, Santa Barbara has produced highly efficient LEDs on (11-22) GaN with over 65 mW output power at 100 mA for blue-emitting devices [1], over 35 mW output power at 100 mA for blue-green emitting devices [2], and over 15 mW of power at 100 mA for green-emitting devices [3]. In [3] it was shown that the indium incorporation on semipolar (11-22) GaN is comparable to or greater than that of c-plane GaN, which provides further promise for achieving high crystal quality extended wavelength emitting InGaN layers.

This rapid progress of semipolar GaN-based emitters at longer wavelengths indicates the imminence of a yellow LED operating in the 560-590 nm range and/or possibly even a red LED operating in the 625-700 nm range on semipolar GaN substrates. Either of these breakthroughs would facilitate a white light source using only GaN based LEDs. In the first case, a blue semipolar LED can be combined with a yellow semipolar LED to form a fully GaN/InGaN-based LED white light source. In the second case, a blue semipolar LED can be combined with a green semipolar LED and a red semipolar LED to form a fully GaN/InGaN-based LED white light source. Both of these technologies would be revolutionary breakthroughs since the inefficient phosphors used in conventional LED based white light sources can be eliminated. Very importantly, the white light source would be highly polarized relative to LED/phosphor based sources, in which the phosphors emit randomly polarized light. Furthermore, since both the blue and the yellow or the blue, green, and red LEDs will be fabricated from the same material system, great fabrication flexibilities can be afforded by way of monolithic integration of the various color LEDs. It is important to note that other semipolar orientations exist such as (10-1-1) plane. White light sources realized by combining blue and yellow or blue, green, and red semipolar LEDs would offer great advantages in applications where high efficiency or polarization are important. Such applications include conventional lighting of homes and businesses, decorative lighting, and backlighting for displays. There are several embodiments for this invention including copackaging discrete blue-yellow or blue-green-red LEDs, or monolithically integrating them on the same chip in a side-by-side configuration, in a stacked junction configuration, or by putting multi-color quantum wells in the same active region.

### BRIEF SUMMARY OF THE INVENTION

According to the present invention, techniques for lighting are provided. More specifically, embodiments of the invention include techniques for combining different colored LED devices, such as blue and yellow, fabricated on bulk semipolar or nonpolar materials. Merely by way of example, the invention can be applied to applications such as white lighting, multi-colored lighting, lighting for flat panels, other optoelectronic devices, and the like.

In a specific embodiment, the present invention provides a packaged light emitting device. The device has a substrate member comprising a surface region. The device also has two or more light emitting diode devices overlying the surface region. Each of the light emitting diode device is fabricated on a semipolar or nonpolar GaN containing substrate. The two or more light emitting diode devices are fabricated on the semipolar or nonpolar GaN containing substrate emits substantially polarized emission.

In an alternative specific embodiment, the present invention provides a monolithic light emitting device. The device has a bulk GaN containing semipolar or nonpolar substrate comprising a surface region. The device also has an n-type GaN containing layer overlying the surface region. The n-type GaN containing layer has a first region and a second region.

The device also has a first LED device having a first color characteristic provided on the first region and a second LED device having a second color characteristic provided on the second region. In a specific embodiment, the first color characteristic is blue and the second color characteristic is yellow.

In yet an alternative embodiment, the present invention provides a monolithic light emitting device. The device has a bulk GaN containing semipolar or nonpolar substrate comprising a surface region. The device has an n-type GaN containing layer overlying the surface region. The n-type GaN containing layer has a first region and a second region. The device has a first LED device having a first color characteristic provided on the first region, a second LED device having a second color characteristic provided on the second region, and a third LED device having a third color characteristic provided on the third region.

In still an alternative embodiment, the present invention provides a light emitting device. The device has a bulk GaN containing semipolar or nonpolar substrate. The bulk GaN containing semipolar or nonpolar substrate comprises a surface region and a bottom region. In a specific embodiment, the device has an n-type GaN containing material overlying the surface region. The device has a blue LED device overlying the surface region, a green LED device overlying the blue LED device, and a red LED device overlying the green LED device to form a stacked structure.

Still further, the present invention provides a light emitting device. The device has a bulk GaN semipolar or nonpolar substrate comprising a surface region. The device has an N-type GaN containing layer overlying the surface region. The device an InGaN active region overlying the surface region. The device has a blue emitting region within a first portion of the InGaN active region and a yellow emitting region within a second portion of the InGaN active region. The device has a p-type GaN containing layer overlying the InGaN active region.

Moreover, in yet an alternative specific embodiment, the present invention provides a light emitting device. The device has a bulk GaN semipolar or nonpolar substrate comprising a surface region. The device has an N-type GaN containing layer overlying the surface region. The device has an InGaN active region overlying the surface region. The device has a blue emitting region within a first portion of the InGaN active region, a green emitting region within a second portion of the InGaN active region, and a red emitting region within a third portion of the InGaN active region. The device further has a p-type GaN containing layer overlying the InGaN active region.

The present invention achieves these benefits and others in the context of known process technology. However, a further understanding of the nature and advantages of the present invention may be realized by reference to the latter portions of the specification and attached drawings.

### BRIEF DESCRIPTION OF THE DRAWINGS

FIG. 1 shows the first embodiment of this invention where FIG. 1a presents copackaged blue and yellow semipolar GaN-based LEDs and FIG. 1b presents copackaged blue, green, and red semipolar GaN-based LEDs. These devices could be wired in series, parallel, or on isolated circuits.

FIG. 2 shows the second embodiment of this invention where FIG. 2a presents monolithic side-by-side blue and yellow semipolar GaN-based LEDs and FIG. 2b presents monolithic side by side blue, green, and red semipolar GaN-based LEDs. These devices could be wired in series, parallel, or on isolated circuits.

FIG. 3 shows the third embodiment of this invention where FIG. 3a presents vertically stacked blue and yellow semipolar GaN-based LEDs and FIG. 3b presents vertically stacked blue, green, and red semipolar GaN-based LEDs. From a growth standpoint, this embodiment would likely make the most sense with the shorter wavelength emitter regions being on the bottom of the stack and then capturing the light out of the bottom of the device. This configuration would need tunnel junctions between the adjacent n-GaN and p-GaN layers.

FIG. 4 shows the fourth embodiment of this invention where FIG. 4a presents blue and yellow emitter layers within the same active region of a semipolar GaN-based LED and FIG. 4b presents blue, green, and red emitter layers within the same active region of a semipolar GaN-based LED. From a growth standpoint, his embodiment would likely make the most sense with the shorter wavelength emitter layers being in the bottom portion of the active region and then capturing the light out of the bottom of the device. This configuration would need tunnel junctions between the adjacent n-GaN and p-GaN layers.

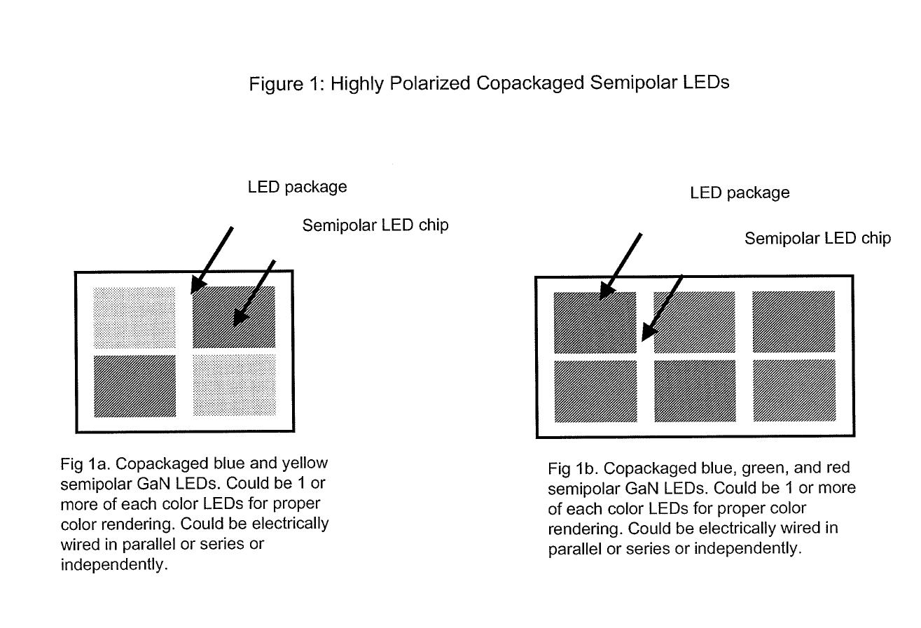

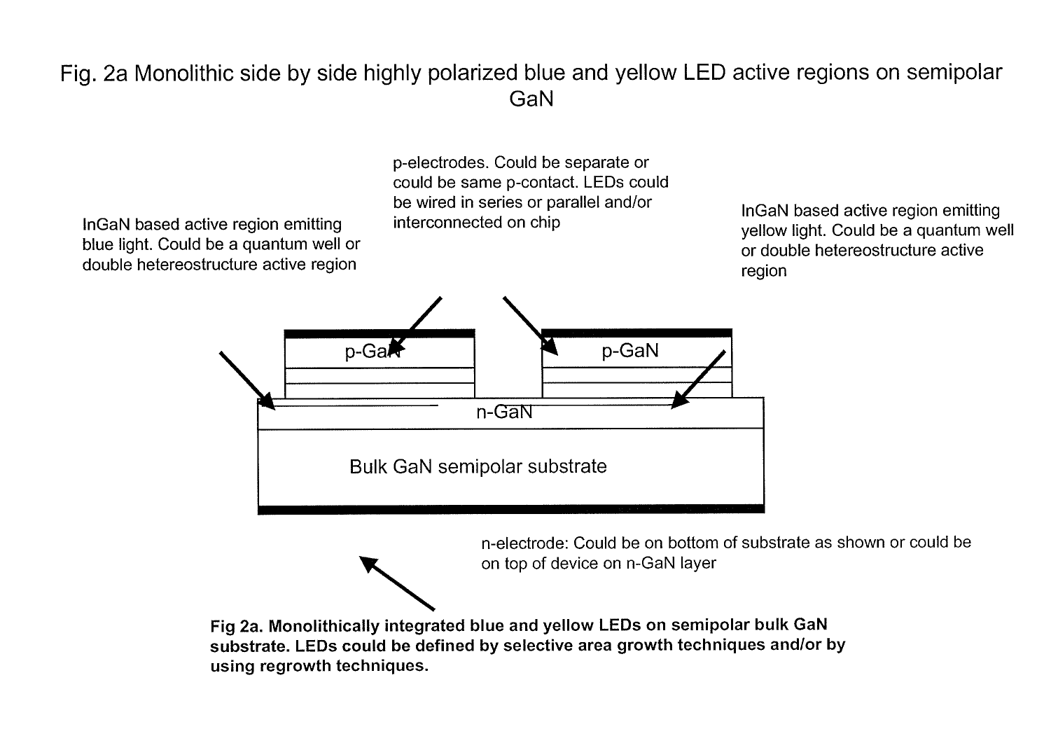

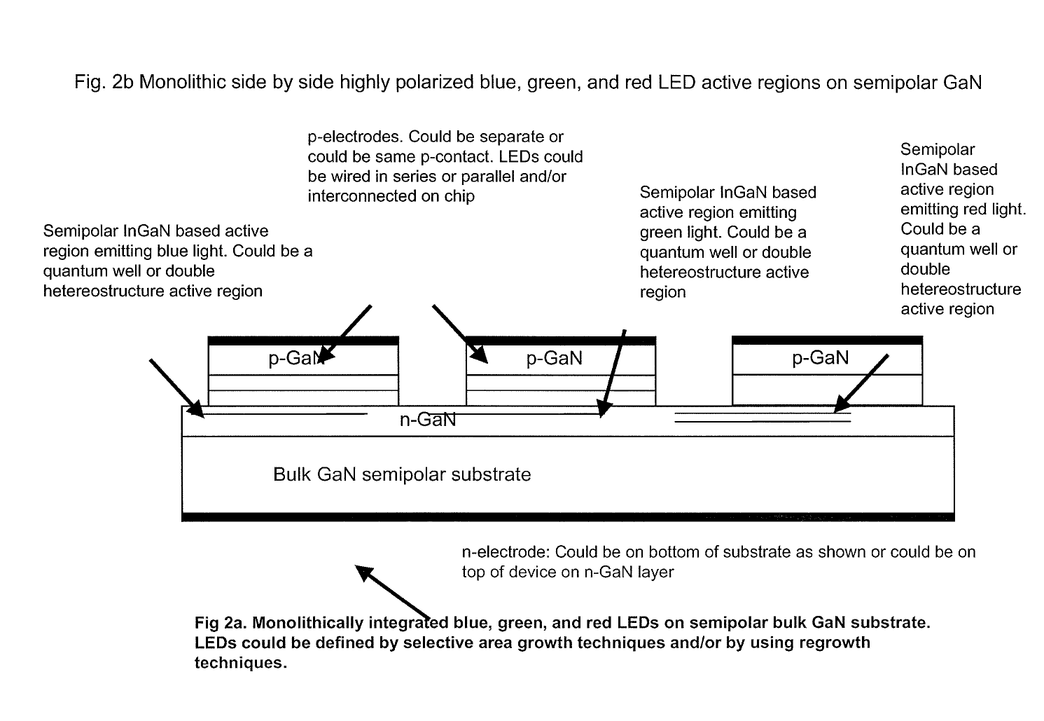

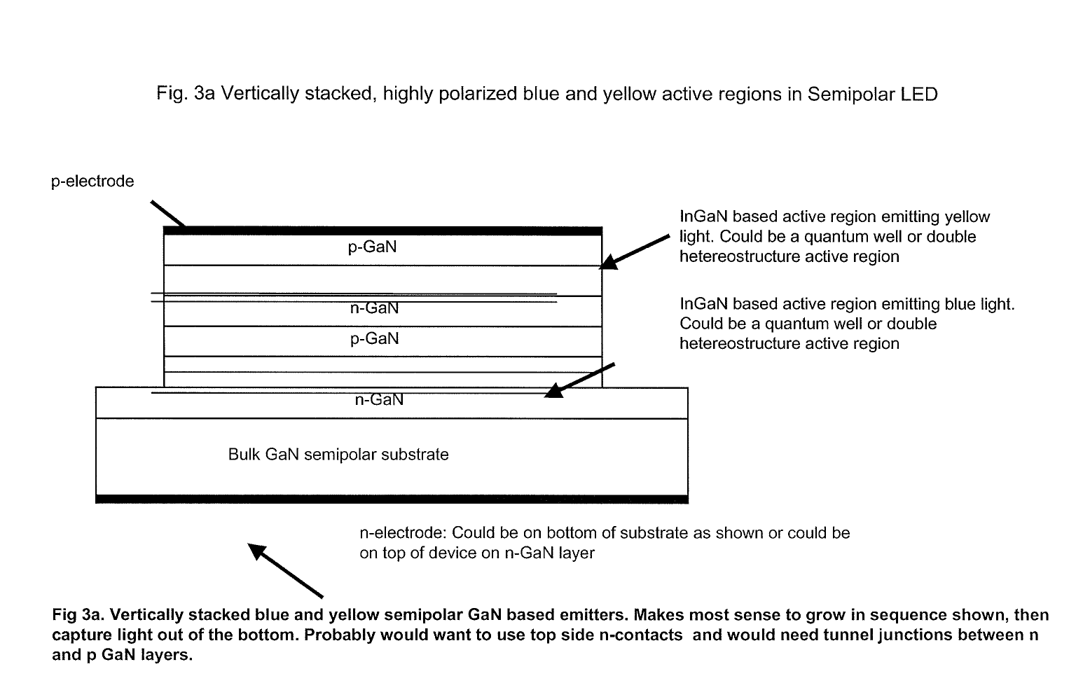

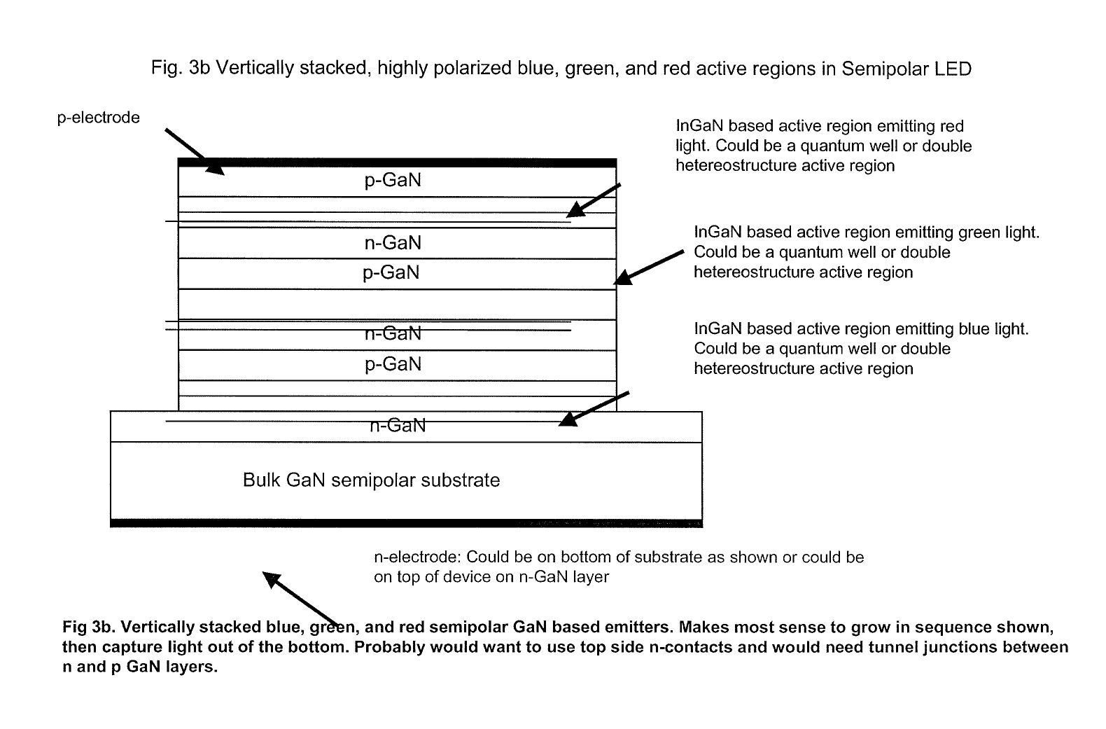

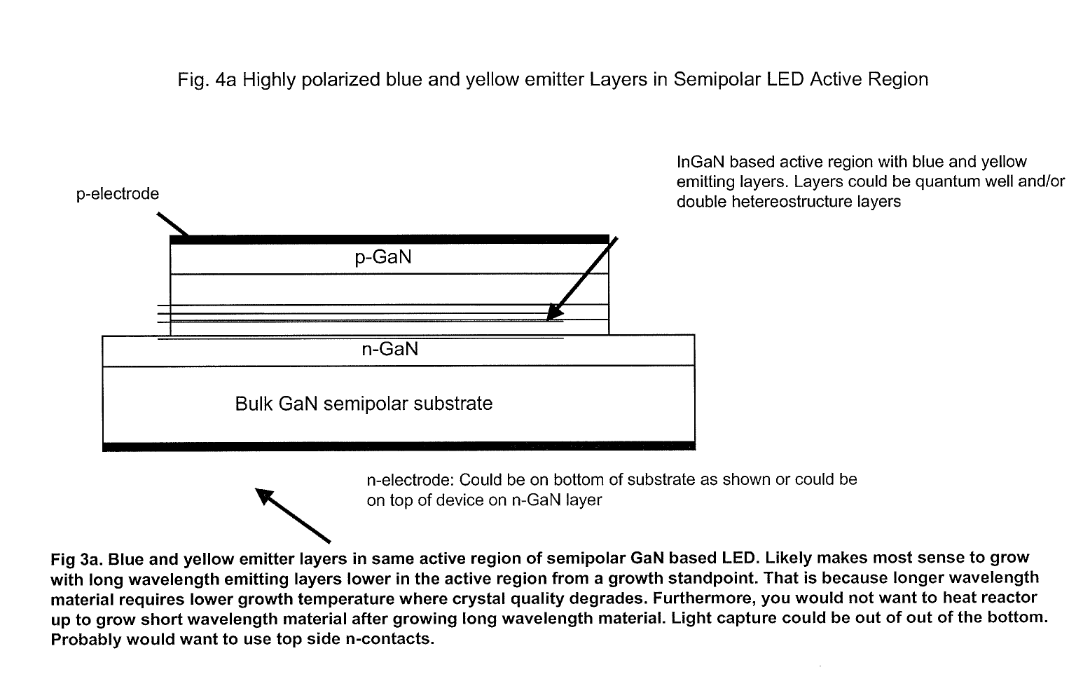

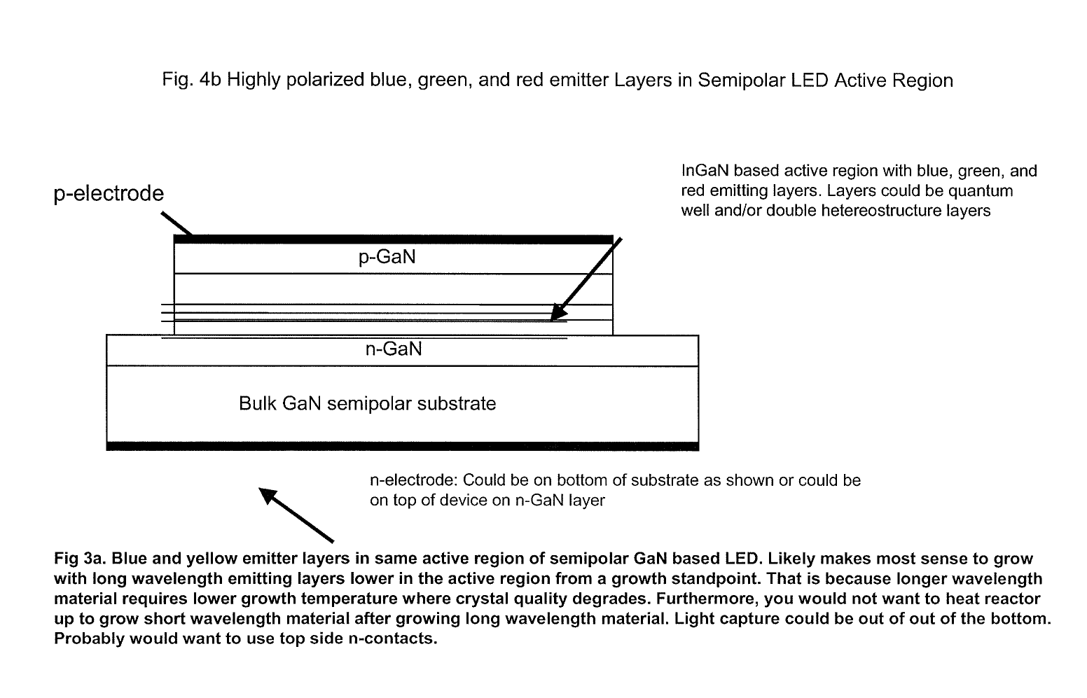

While the above is a full description of the specific embodiments, various modifications, alternative constructions and equivalents may be used. Therefore, the above description and illustrations should not be taken as limiting the scope of the present invention which is defined by the appended claims.

What is claimed is:

1. A packaged light emitting device comprising:
a substrate member comprising a surface region;
two or more light emitting diode devices overlying the surface region, each of the light emitting diode device being fabricated on a semipolar or nonpolar GaN containing substrate, the two or more light emitting diode devices fabricated on the semipolar or nonpolar GaN containing substrate emits substantially polarized emission.

2. The device of claim 1 wherein the two or more light emitting diode device comprising a blue LED device and a yellow LED device, the substantially polarized emission being white light.

3. The device of claim 1 wherein the two or more light emitting diode device comprises an array of LED devices comprising a pair of blue LED devices and a pair of yellow LED devices.

4. The device of claim 1 wherein the two or more light emitting diode devices comprises at least a red LED device, a blue LED device, and a green LED device.

5. A monolithic light emitting device comprising:
a bulk GaN containing semipolar or nonpolar substrate comprising a surface region;
an n-type GaN containing layer overlying the surface region, the n-type GaN containing layer having a first region and a second region;
a first LED device provided on the first region, the first LED device having a first color characteristic; and
a second LED device provided on the second region, the second LED device having a second color characteristic.

6. The device of claim 5 wherein the first color characteristic is yellow and the second color characteristic is blue.

7. The device of claim 6 further comprising a third LED device provided on a third region, the third LED device having a third color characteristic, the third color characteristic being red or green.

8. A monolithic light emitting device comprising:
a bulk GaN containing semipolar or nonpolar substrate comprising a surface region;
an n-type GaN containing layer overlying the surface region, the n-type GaN containing layer having a first region and a second region;
a first LED device provided on the first region, the first LED device having a first color characteristic;
a second LED device provided on the second region, the second LED device having a second color characteristic; and
a third LED device provided on the third region, the third LED device having a third color characteristic.

9. The device of claim 8 wherein the first characteristic is blue, the second characteristic is green, and the third characteristic is red.

10. A light emitting device comprising:
a bulk GaN containing semipolar or nonpolar substrate, the bulk GaN containing semipolar or nonpolar substrate comprising a surface region and a bottom region;
an n-type GaN containing material overlying the surface region;
a blue LED device overlying the surface region;
a yellow LED device overlying the blue LED device to form a stacked structure.

11. The device of claim 10 further comprising a red LED device overlying the blue LED device.

12. The device of claim 10 wherein the blue LED device and the yellow LED device are configured to emit substantially polarized emission.

13. A light emitting device comprising:
a bulk GaN containing semipolar or nonpolar substrate, the bulk GaN containing semipolar or nonpolar substrate comprising a surface region and a bottom region;
an n-type GaN containing material overlying the surface region;
a blue LED device overlying the surface region;
a green LED device overlying the blue LED device;
a red LED device overlying the green LED device to form a stacked structure.

14. A light emitting device comprising:
a bulk GaN semipolar or nonpolar substrate comprising a surface region;
an N-type GaN containing layer overlying the surface region;
an InGaN active region overlying the surface region;
a blue emitting region within a first portion of the InGaN active region;
a yellow emitting region within a second portion of the InGaN active region;
a p-type GaN containing layer overlying the InGaN active region.

15. A light emitting device comprising:
a bulk GaN semipolar or nonpolar substrate comprising a surface region;
an N-type GaN containing layer overlying the surface region;
an InGaN active region overlying the surface region;
a blue emitting region within a first portion of the InGaN active region;
a green emitting region within a second portion of the InGaN active region;
a red emitting region within a third portion of the InGaN active region; and
a p-type GaN containing layer overlying the InGaN active region.
